(19) United States
(12) Patent Application Publication
(10) Pub. No.: US 2025/0040371 A1
(43) Pub. Date: Jan. 30, 2025

(54) DISPLAY DEVICE AND METHOD OF FABRICATING THE SAME

(71) Applicant: Samsung Display Co., LTD., Yongin-si (KR)

(72) Inventors: Seung Min LEE, Yongin-si (KR); Hyun KIM, Yongin-si (KR); Souk June HWANG, Yongin-si (KR)

(21) Appl. No.: 18/628,734

(22) Filed: Apr. 7, 2024

(30) Foreign Application Priority Data
Jul. 26, 2023 (KR) 10-2023-0097437

(51) Int. Cl. H10K 59/131; H10K 59/12; H10K 59/40

(52) U.S. Cl. CPC H10K 59/131; H10K 59/1201; H10K 59/40

(57) ABSTRACT

A display device includes a substrate having a first side surface adjacent to an upper surface, a second side surface adjacent to a lower surface, and an opening surrounded by the second side surface, a pad clad surrounded by the first side surface of the substrate and including a pad contact hole, a pad disposed on the pad clad and inserted into the pad contact hole, a fan-out line disposed on the pad and electrically connected to the pad, a transistor electrically connected to the fan-out line, and a flexible film disposed under the substrate and including a lead electrode inserted into the opening of the substrate and in contact with the pad.

This application claims priority to Korean Patent Application No. 10-2023-0097437, filed on Jul. 26, 2023, and all the benefits accruing therefrom under 35 U.S.C. § 119, the content of which in its entirety is herein incorporated by reference.

### BACKGROUND

### 1. Field

The disclosure relates to a display device and a method of fabricating the same.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. Display devices may be flat panel display devices such as a liquid-crystal display device, a field emission display device, and an organic light-emitting display device. Among such flat panel display devices, a light-emitting display device includes a light-emitting element that may emit light on its own, so that each of pixels of the display panel may emit light by themselves. Accordingly, a light-emitting display device may display images without a backlight unit that supplies light to the display panel.

### SUMMARY

Features of the disclosure provide a display device in which pads disposed on a substrate and flexible films disposed under the substrate may be electrically connected, and a method of fabricating the same.

Features of the disclosure also provide a display device that may save fabrication time and cost by way of reducing the non-display area and simplifying the fabrication process, and a method of fabricating the same.

It should be noted that features of the disclosure are not limited to the above-mentioned feature; and other features of the disclosure will be apparent to those skilled in the art from the following descriptions.

In an embodiment of the disclosure, a display device includes a substrate which includes a first side surface adjacent to an upper surface and a second side surface adjacent to a lower surface, and in which an opening surrounded by the second side surface is defined, a pad clad surrounded by the first side surface of the substrate and including a pad contact hole, a pad disposed on the pad clad and inserted into the pad contact hole, a fan-out line disposed on the pad and electrically connected to the pad, a transistor electrically connected to the fan-out line, and a flexible film disposed under the substrate and including a lead electrode inserted into the opening of the substrate and in contact with the pad.

In an embodiment, the display device may further include a contact part covering a lower surface of the lead electrode and a lower surface of the pad to electrically connect the lead electrode with the pad.

In an embodiment, the lead electrode may protrude from one side of the flexible film. The contact part may cover the lower surface of the lead electrode protruding from the flexible film.

In an embodiment, an upper surface of the pad clad may be flush with the upper surface of the substrate.

In an embodiment, the pad clad may include at least one of polyimide (“PI”), silicon nitride (SiNx), and silicon (Si).

In an embodiment, the pad clad may be exposed through the opening of the substrate.

In an embodiment, the first side surface of the substrate may be inclined at a first angle with respect to a same plane as a plane of the upper surface of the substrate, and the second side surface of the substrate may be inclined at a second angle with respect to a same plan as the lower surface of the substrate. The first angle may be smaller than the second angle.

In an embodiment, a vertical thickness of the first side surface may be smaller than a vertical thickness of the second side surface.

In an embodiment, the contact part may be formed using a metal paste including or consisting of silver (Ag) or copper (Cu).

In an embodiment, the display device may further include a display area which displays images, and a non-display area surrounding the display area. The pad and the flexible film may be disposed in the display area.

In an embodiment, the display device may further include a display area which displays images, a non-display area surrounding the display area, and a display driver which is disposed on the flexible film and applies a data voltage to the transistor. The pad and the fan-out line may be disposed in the non-display area, and the display driver may be disposed in the display area.

In an embodiment, the display device may further include a transistor layer including the transistor, a light-emitting element layer disposed on the transistor layer and comprising a light-emitting element, and an encapsulation layer covering upper and side surfaces of the light-emitting element layer.

In an embodiment, the display device may further comprise a transistor layer comprising the transistor, a light-emitting element layer disposed on the transistor layer and comprising a light-emitting element, an encapsulation substrate disposed on the light-emitting element layer, and a sealing member disposed along edges of the substrate and the encapsulation substrate between the substrate and the encapsulation substrate to attach the substrate and the encapsulation substrate to each other.

In an embodiment of the disclosure, a method of fabricating a display device comprises providing a substrate, defining a groove in the substrate by performing a first etching process on an upper surface of the substrate, forming a pad clad that is accommodated in the groove and includes a pad contact hole, forming a pad disposed on the pad clad and inserted into the pad contact hole, forming a transistor on the pad and forming a fan-out line electrically connecting the pad with the transistor, defining an opening exposing the pad by performing a secondary etching process on a lower surface of the substrate, and inserting one side of a flexible film into the opening to bring a lead electrode of the flexible film in contact with the pad.

In an embodiment, the method may further comprise forming a contact part electrically connecting the pad with the lead electrode by covering a part of the pad and a part of the lead electrode.

In an embodiment, the forming the contact part may comprise printing a metal paste on the opening of the substrate and then sintering the metal paste.

In an embodiment, the forming the contact part may further comprise separating a sintered metal paste into a plurality of contact parts via a laser patterning process.

In an embodiment, the forming the pad clad may comprise disposing an upper surface of the pad clad so that the upper surface of the pad clad is flush with the upper surface of the substrate.

In an embodiment, the defining the groove in the substrate may comprise forming a first side surface inclined at a first angle from a same plane as a plane of the upper surface of the substrate. The defining the opening may comprise forming a second side surface inclined at a second angle from a same plane as a plane of the lower surface of the substrate. The first angle may be smaller than the second angle.

In an embodiment, a thickness of the pad clad may be smaller than a depth of the opening.

In an embodiment of the disclosure, a pad clad may be formed in a groove of a substrate formed via a first etching process of the substrate, a pad may be inserted into a pad contact hole of the pad clad, a lead electrode of a flexible film may be inserted into an opening of the substrate formed via a second etching process of the substrate so that the lead electrode may be brought into contact with the pad, and the pad disposed on the substrate may be electrically connected to the flexible film disposed under the substrate.

In the embodiment of the disclosure, the non-display area may be reduced by including the flexible film and the display driver disposed under the substrate. By way of fixing a lead electrode and a pad by a contact part using a metal paste and electrically connecting between them, the fabrication process may be simplified without using ultrasonic bonding or thermocompression bonding, so that the fabrication time and cost may be saved.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is a plan view showing an embodiment of a display device according to the disclosure.

FIG. 2 is a cross-sectional view showing an embodiment of a display device according to the disclosure.

FIG. 3 is a cross-sectional view showing an embodiment of a display device according to the disclosure.

FIG. 4 is a cross-sectional view, taken along line I-I′ of FIG. 1.

FIG. 5 is an enlarged view of area A1 of FIG. 4.

FIG. 6 is a view showing the bottom of an embodiment of a display device according to the disclosure.

FIG. 7 is an enlarged view showing an embodiment of a part of the bottom of the display device in the embodiment of the disclosure.

FIG. 8 is a view showing an embodiment of the bottom of a display device according to the disclosure.

FIG. 9 is a circuit diagram showing an embodiment of a pixel of a display device according to the disclosure.

FIGS. 10 to 15 are cross-sectional views showing an embodiment of processing operations of fabricating a display device according to the disclosure.

### DETAILED DESCRIPTION

In the following description, for the purposes of explanation, numerous specific details are set forth in order to provide a thorough understanding of various embodiments or implementations of the disclosure. As used herein “embodiments” and “implementations” are interchangeable words that are non-limiting embodiments of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or features, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/of” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

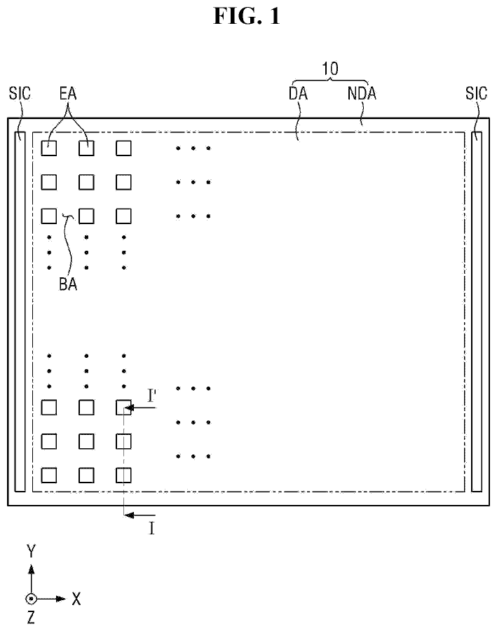

FIG. 1 is a plan view showing an embodiment of a display device according to the disclosure.

Referring to FIG. 1, a display device 10 may be employed by portable electronic devices such as a mobile phone, a smart phone, a tablet personal computer (“PC”), a mobile communications terminal, an electronic notebook, an electronic book, a portable multimedia player (“PMP”), a navigation device and an ultra mobile PC (“UMPC”). In another embodiment, the display device 10 may be used as a display unit of a television, a laptop computer, a monitor, an electronic billboard, or the Internet of Things (“IoT”). In another embodiment, the display device 10 may be applied to wearable devices such as a smart watch, a watch phone, a glasses-type display, and a head-mounted display (“HMD”) device.

The display device 10 may have a shape similarly to a quadrangular shape when viewed from the top. In an embodiment, the corners where the sides in the x-axis direction and the sides in the y-axis direction meet each other may be rounded to have a predetermined curvature or may be formed at a right angle, for example. The shape of the display device 10 when viewed from the top is not limited to a quadrangular shape, but may be formed in a shape similar to other polygonal shapes, a circular shape, or an elliptical shape.

The display device 10 may include a display area DA and a non-display area NDA. The display area DA may include a plurality of pixels to display images. Each of a plurality of pixels may include an organic light-emitting diode (“LED”) including an organic light-emitting layer, a quantum-dot LED including a quantum-dot light-emitting layer, an inorganic LED including an inorganic semiconductor, or a micro LED. In the following description, each of the pixels includes an organic LED. It is, however, to be understood that the disclosure is not limited thereto.

The pixels may be arranged in rows and columns in the display area DA. Each of the pixels may include an emission area EA defined by a pixel-defining film or a bank, and may emit light having a predetermined peak wavelength through the emission area EA. In the emission area EA, light generated by light-emitting element of the display device 10 exits out of the display device 10.

The display area DA of the display device 10 may include light-blocking areas BA surrounding the plurality of emission areas EA. The light-blocking areas BA may prevent color mixing of lights output from the emission areas EA.

The non-display area NDA may be disposed around the display area DA to surround the display area DA, and may display no image. The non-display area NDA may include a scan driver SIC providing scan signals to the display area DA. The scan driver SIC may be disposed on the left side and the right side of the non-display area NDA. The scan driver SIC may generate the scan signals based on a scan control signal. The scan control signal may include, but is not limited to, a start signal, a clock signal, and a supply voltage. The scan driver SIC may provide the scan signals to scan lines of the display area DA in a predetermined order.

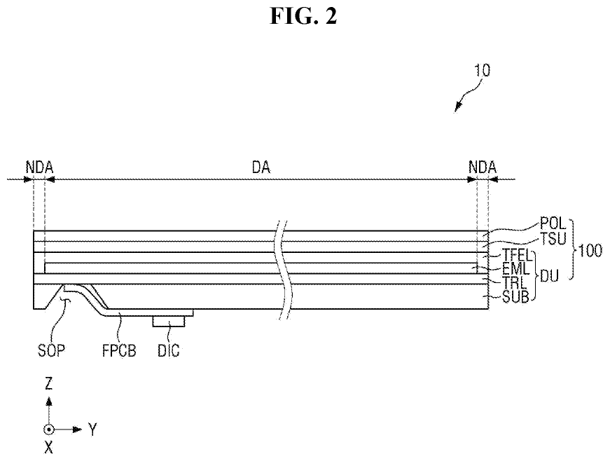

FIG. 2 is a cross-sectional view showing an embodiment of a display device according to the disclosure.

Referring to FIG. 2, the display panel 100 may include a display unit DU, a touch sensing unit TSU, and a polarizing film POL. The display unit DU may include a substrate SUB, a transistor layer TRL, a light-emitting element layer EML and an encapsulation layer TFEL.

The substrate SUB may be a base substrate or a base member. In an embodiment, the substrate SUB may be, but is not limited to, a rigid substrate including glass material or metal material, for example. In another embodiment, the substrate SUB may be a flexible substrate including a polymer resin such as polyimide (“PI”).

The transistor layer TRL may be disposed on the substrate SUB. The transistor layer TRL may include a plurality of transistors forming pixel circuits of pixels. The transistor layer TRL may include scan lines, data lines, and power lines connected to pixels. Each of the transistors may include a semiconductor region, a source electrode, a drain electrode, and a gate electrode. In an embodiment, when the scan driver is formed on one side of the non-display area NDA of the display panel 100, the scan driver may include transistors, for example.

The transistor layer TRL may be disposed in the display area DA and the non-display area NDA. Transistors, scan lines, data lines and power lines in the transistor layer TRL for the pixels may be disposed in the display area DA. The transistors of the scan driver SIC may be disposed in the non-display area NDA.

The light-emitting element layer EML may be disposed on the transistor layer TRL. The light-emitting element layer EML may include a plurality of light-emitting elements in each of which a pixel electrode, an emissive layer and a common electrode are stacked on one another sequentially to emit light, and a pixel-defining film for defining the pixels. The plurality of light-emitting elements in the light-emitting element layer EML may be disposed in the display area DA.

In an embodiment, the emissive layer may be an organic light-emitting layer including or consisting of an organic material, for example. The emissive layer may include a hole transporting layer, an organic light-emitting layer and an electron transporting layer. When the pixel electrode receives a voltage and the common electrode receives a cathode voltage through the transistor in the transistor layer TRL, holes may move to the organic light-emitting layer through the hole transporting layer, and electrons may move to the organic light-emitting layer through the electron transporting layer, such that they combine in the organic light-emitting layer to emit light. In an embodiment, the pixel electrode may be an anode electrode while the common electrode may be a cathode electrode, for example. It is, however, to be understood that the disclosure is not limited thereto.

In another embodiment, the light-emitting elements may include quantum-dot LEDs each including a quantum-dot emissive layer, inorganic LEDs each including an inorganic semiconductor, or micro LEDs.

An encapsulation layer TFEL may cover the upper and side surfaces of the light-emitting element layer EML, and may protect the light-emitting element layer EML. The encapsulation layer TFEL may include at least one inorganic layer and at least one organic layer for encapsulating the light-emitting element layer EML.

The touch sensing unit TSU may be disposed on the encapsulation layer TFEL. The touch sensing unit TSU may include a plurality of touch electrodes for sensing a user's touch by capacitive sensing, and touch lines providing the plurality of touch electrodes with touch driving signals. In an embodiment, the touch sensing unit TSU may sense a user's touch by mutual capacitance sensing or self-capacitance sensing, for example.

The plurality of touch electrodes of the touch sensing unit TSU may be disposed in a touch sensor area overlapping with the display area DA. The touch lines of the touch sensing unit TSU may be disposed in a touch peripheral area overlapping with the non-display area NDA.

The polarizing film POL may be disposed on the touch sensing unit TSU. The polarizing film POL may be attached on the touch sensing unit TSU by an optically clear adhesive (“OCA”) film or an optically clear resin (“OCR”). In an embodiment, the polarizing film POL may include a linear polarizer and a retarder film, for example. The retarder film may be a V/4 plate (quarter-wave plate). The retarder film and the linear polarizer may be sequentially stacked on the touch sensing unit TSU. The polarizing film POL may reduce reflection of external light to prevent color distortion due to the reflection of external light.

An opening SOP may be defined in the substrate SUB. The opening SOP of the substrate SUB may be etched so that it penetrates from the lower surface of the substrate SUB to the upper surface of the substrate SUB. In an embodiment, the width of the bottom of the opening SOP may be greater than the width of the top of the opening SOP, for example. During the processes of fabricating the display device 10, a pad disposed in the transistor layer TRL may be exposed by the opening SOP of the substrate SUB. The pad may be electrically connected to a display driver DIC through a flexible film FPCB inserted into the opening SOP.

The flexible film FPCB may be disposed under the substrate SUB. A part of the flexible film FPCB may be inserted into the opening SOP of the substrate SUB and electrically connected to the pad. Another part of the flexible film FPCB may be attached to the lower surface of the substrate SUB. The flexible film FPCB may support the display driver DIC. The flexible film FPCB may transmit signals and voltages from the display driver DIC to the transistor layer TRL. The flexible film FPCB may supply a scan control signal to the scan driver SIC.

The display driver DIC may be disposed (e.g., mounted) on the flexible film FPCB. The display driver DIC may be an integrated circuit (“IC”). The display driver DIC may convert digital video data into analog data voltage based on a data control signal from a timing controller (not shown), and may supply it to the data lines in the display area DA through the flexible film FPCB. The display driver DIC may supply the power voltage received from the power supply unit (not shown) to the power lines in the display area DA through the flexible film FPCB. As the display device 10 includes the flexible film FPCB and the display driver DIC disposed in the display area DA under the substrate SUB, the non-display area NDA may be reduced.

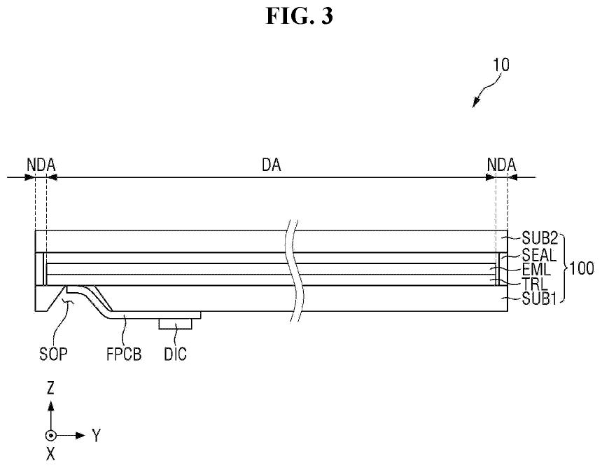

FIG. 3 is a cross-sectional view showing an embodiment of a display device according to the disclosure.

Referring to FIG. 3, the display panel 100 may include a first substrate SUB1, a transistor layer TRL, a light-emitting element layer EML, a sealing member SEAL, and a second substrate SUB2.

The first substrate SUB1 may be abase substrate or abase member. In an embodiment, the first substrate SUB1 may be, but is not limited to, a rigid substrate including glass material or metal material, for example. In another embodiment, the first substrate SUB1 may be a flexible substrate including a polymer resin such as PI.

The transistor layer TRL may be disposed in the display area DA on the first substrate SUB1. The transistor layer TRL may include a plurality of transistors forming pixel circuits of pixels. The transistor layer TRL may include scan lines, data lines, and power lines connected to the pixels. Each of the transistors may include a semiconductor region, a source electrode, a drain electrode, and a gate electrode.

The light-emitting element layer EML may be disposed on the transistor layer TRL. The light-emitting element layer EML may include a plurality of light-emitting elements in each of which a pixel electrode, an emissive layer and a common electrode are stacked on one another sequentially to emit light, and a pixel-defining film for defining the pixels. The plurality of light-emitting elements in the light-emitting element layer EML may be disposed in the display area DA.

The sealing member SEAL may be disposed between the first substrate SUB1 and the second substrate SUB2. The sealing member SEAL may be disposed along the edges of the non-display area NDA, and may attach the first and second substrates SUB1 and SUB2 together. The sealing member SEAL may protect the side surfaces of the display panel 100.

The second substrate SUB2 may be disposed on the display panel 100 to protect the transistor layer TRL and the light-emitting element layer EML. The second substrate SUB2 may be an encapsulation substrate encapsulating the transistor layer TRL and the light-emitting element layer EML. In an embodiment, the second substrate SUB2 may include, but is not limited to, a glass material or a metal material, for example.

An opening SOP may be defined in the first substrate SUB1. The opening SOP of the first substrate SUB1 may be etched so that it penetrates from the lower surface of the first substrate SUB1 to the upper surface of the first substrate SUB1. In an embodiment, the width of the bottom of the opening SOP may be greater than the width of the top of the opening SOP, for example. During the process of fabricating the display device 10, a pad disposed in the transistor layer TRL may be exposed by the opening SOP of the first substrate SUB1. The pad may be electrically connected to a display driver DIC through a flexible film FPCB inserted into the opening SOP.

The flexible film FPCB may be disposed under the first substrate SUB1. A part of the flexible film FPCB may be inserted into the opening SOP of the first substrate SUB1 and electrically connected to the pad. Another part of the flexible film FPCB may be attached to the lower surface of the first substrate SUB1. The flexible film FPCB may support the display driver DIC. The flexible film FPCB may transmit signals and voltages from the display driver DIC to the transistor layer TRL.

The display driver DIC may be disposed (e.g., mounted) on the flexible film FPCB. The display driver DIC may be an IC. The display driver DIC may convert digital video data into analog data voltage based on a data control signal from a timing controller (not shown), and may supply it to the data lines in the display area DA through the flexible film FPCB. The display driver DIC may supply the power voltage received from the power supply unit (not shown) to the power lines in the display area DA through the flexible film FPCB. As the display device 10 includes the flexible film FPCB and the display driver DIC disposed under the first substrate SUB1, the non-display area NDA may be reduced.

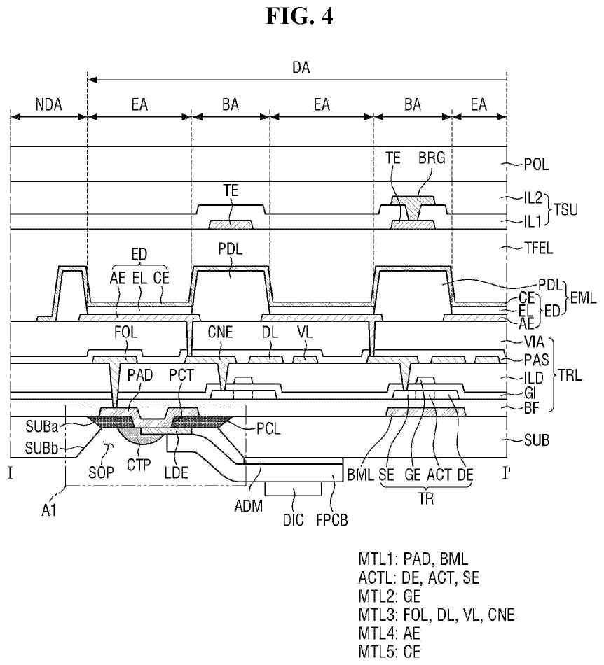

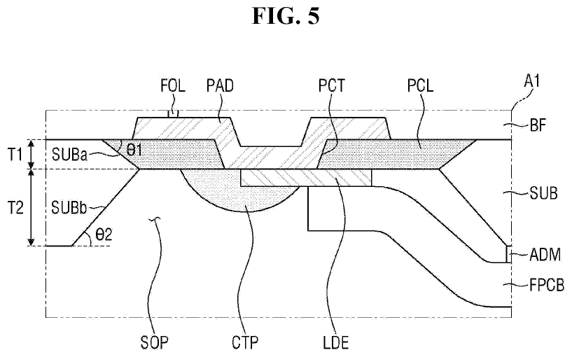

FIG. 4 is a cross-sectional view, taken along line I-I′ of FIG. 1. FIG. 5 is an enlarged view of area A1 of FIG. 4.

Referring to FIGS. 4 and 5, the display area DA of the display device 10 may include a plurality of emission areas EA. In each of the emission areas EA, light generated by the light-emitting element ED exits out of the display device 10.

The display device 10 may include the substrate SUB, the transistor layer TRL, the light-emitting element layer EML, the encapsulation layer TFEL, the touch sensing unit TSU, the polarizing film POL, the flexible film FPCB, and the display driver DIC.

The substrate SUB may support the display device 10. The substrate SUB may be a base substrate or a base member. In an embodiment, the substrate SUB may be, but is not limited to, a rigid substrate including glass material or metal material, for example. In another embodiment, the substrate SUB may be a flexible substrate including a polymer resin such as PI.

An opening SOP may be defined in the substrate SUB. The opening SOP of the substrate SUB may be etched so that it penetrates from the lower surface of the substrate SUB to the upper surface of the substrate SUB. In an embodiment, the width of the bottom of the opening SOP may be greater than the width of the top of the opening SOP, for example. During the processes of fabricating the display device 10, a pad PAD may be exposed by the opening SOP of the substrate SUB. The pad PAD may be electrically connected to a display driver DIC through a flexible film FPCB inserted into the opening SOP.

In FIG. 5, a first side surface SUBa of the substrate SUB may be formed via a first etching process of the substrate SUB, and a second side surface SUBb of the substrate SUB may be formed via a second etching process of the substrate SUB. The first side surface SUBa of the substrate SUB may surround a pad clad PCL, and the second side surface SUBb of the substrate SUB may surround the opening SOP. The first side surface SUBa of the substrate SUB may be formed by etching from the upper surface of the substrate SUB, and the second side surface SUBb of the substrate SUB may be formed by etching from the lower surface of the substrate SUB. The first side surface SUBa of the substrate SUB may be adjacent to the upper surface of the substrate SUB, and the second side surface SUBb of the substrate SUB may be adjacent to the lower surface of the substrate SUB. The second side surface SUBb of the substrate SUB may be disposed between the first side surface SUBa and the lower surface of the substrate SUB. The first side surface SUBa of the substrate SUB may be inclined at a first angle θ1 relative to a same plane as that of the upper surface of the substrate SUB. The second side surface SUBb of the substrate SUB may be inclined at a second angle θ2 relative to a same plane as that of the lower surface of the substrate SUB. The first angle θ1 of the first side surface SUBa may be smaller than the second angle θ2 of the second side surface SUBb. The vertical thickness T1 of the first side surface SUBa may be smaller than the vertical thickness T2 of the second side surface SUBb. The vertical thickness T1 of the first side surface SUBa may be equal to the thickness of the pad clad PCL, and the vertical thickness T2 of the second side surface SUBb may be equal to the depth of the opening SOP. The sum of the vertical thickness T1 of the first side surface SUBa and the vertical thickness T2 of the second side surface SUBb may be equal to the thickness of the substrate SUB. In an embodiment, the vertical thickness T1 of the first side surface SUBa may be approximately 1 micrometer (m) to approximately 10 m, and the vertical thickness T2 of the second side surface SUBb may be approximately 180 m or more, for example, but the thicknesses are not limited thereto.

The pad clad PCL may be surrounded by the first side surface SUBa of the substrate SUB. The pad clad PCL may be accommodated in a groove defined in the first etching process of the substrate SUB. The upper surface of the pad clad PCL may be flush with the upper surface of the substrate SUB, but the disclosure is not limited thereto. The pad clad PCL may include a pad contact hole PCT overlapping the opening SOP of the substrate SUB. In the second etching process of the substrate SUB, the pad clad PCL may protect a part of the pad PAD that is not inserted into the pad contact hole PCT. After the second etching process of the substrate SUB is completed, the pad clad PCL may expose another part of the pad PAD inserted into the pad contact hole PCT. Since the display device 10 may include the pad clad PCL, it may protect the transistor layer TRL including the pad PAD in the second etching process of the substrate SUB. In an embodiment, the pad clad PCL may include, but is not limited to, a polymer resin such as PI, or an insulating material such as silicon nitride (SiNx) and silicon (Si), for example.

The transistor layer TRL may be disposed on the substrate SUB and the pad clad PCL. The transistor layer TRL may include a first metal layer MTL1, a buffer layer BF, an active layer ACTL, a gate insulator GI, a second metal layer MTL2, an inter-dielectric layer ILD, a third metal layer MTL3, a passivation layer PAS, and a via layer VIA.

The first metal layer MTL1 may be disposed on the substrate SUB and the pad clad PCL. The first metal layer MTL1 may include a pad PAD and a light-blocking layer BML. The first metal layer MTL1 may include or consist of a single layer or multiple layers including at least one of: molybdenum (Mo), aluminum (Al), chromium (Cr), platinum (Pt), gold (Au), silver (Ag), titanium (Ti), nickel (Ni), palladium (Pd), indium (In), neodymium (Nd), tungsten (W), and copper (Cu).

The pad PAD may be disposed on the pad clad PCL and inserted into the pad contact hole PCT formed in the pad clad PCL. The pad PAD may electrically connect the flexible film FPCB with a fan-out line FOL. The pad PAD may be exposed through the opening SOP of the substrate SUB. A part of the pad PAD may contact a lead electrode LDE of the flexible film FPCB, and another part of the pad PAD may be electrically connected to the lead electrode LDE of the flexible film FPCB through a contact part CTP.

The light-blocking layer BML may be disposed on the substrate SUB. The light-blocking layer BML may overlap with a semiconductor region ACT of a transistor TR. The light-blocking layer BML may block light incident from below the transistor TR.

The buffer layer BF may be disposed on the first metal layer MTL1, the substrate SUB, and the pad clad PCL. The buffer layer BF may include an inorganic material that may prevent the permeation of air or moisture. In an embodiment, the buffer layer BF may include a plurality of inorganic films stacked on one another alternately, for example. The buffer layer BF may define a contact hole through which the fan-out line FOL passes.

The active layer ACTL may be disposed on the buffer layer BF. The active layer ACTL may include the semiconductor region ACT, the drain electrode DE and the source electrode SE of the transistor TR. The semiconductor region ACT may overlap with a gate electrode GE in the thickness direction (z-axis direction) and may be insulated from the gate electrode GE by the gate insulator GI. The drain electrode DE and the source electrode SE may be formed by making the material of the semiconductor region ACT conductive. The transistor TR may form a pixel circuit of each of a plurality of pixels.

The gate insulator GI may be disposed on the active layer ACTL and the buffer layer BF. The gate insulator GI may insulate between the semiconductor region ACT of the transistor TR and the gate electrode GE. The gate insulator GI may define contact holes through which the fan-out line FOL and a connection electrode CNE pass.

The second metal layer MTL2 may be disposed on the gate insulator GI. The second metal layer MTL2 may include the gate electrode GE of the transistor TR. The gate electrode GE may overlap with the semiconductor region ACT with the gate insulator GI interposed therebetween. The gate electrode GE may receive scan signals from the scan lines. In an embodiment, the second metal layer MTL2 may include or consist of a single layer or multiple layers including at least one of: molybdenum (Mo), aluminum (Al), chromium (Cr), gold (Au), silver (Ag), titanium (Ti), nickel (Ni), palladium (Pd), indium (In), neodymium (Nd), and copper (Cu), for example.

The inter-dielectric layer ILD may be disposed on the second metal layer MTL2. The inter-dielectric layer ILD may insulate between the second and third metal layers MTL2 and MTL3. The inter-dielectric layer ILD may define contact holes through which the fan-out line FOL and the connection electrode CNE pass.

The third metal layer MTL3 may be disposed on the inter-dielectric layer ILD. The third metal layer MTL3 may include the fan-out line FOL, the connection electrode CNE, a data line DL, and a voltage line VL. The fan-out line FOL, the connection electrode CNE, the data line DL and the voltage line VL may include or consist of the same material in the same layer. In an embodiment, the third metal layer MTL3 may include or consist of a single layer or multiple layers including at least one of: molybdenum (Mo), aluminum (Al), chromium (Cr), gold (Au), silver (Ag), titanium (Ti), nickel (Ni), palladium (Pd), indium (In), neodymium (Nd), and copper (Cu), for example.

The fan-out line FOL may be inserted into a contact hole penetrating the inter-dielectric layer ILD, the gate insulator GI and the buffer layer BF to be connected to the pad PAD. The fan-out line FOL may overlap with at least one emission area EA. The fan-out line FOL may be electrically connected to the data line DL or voltage line VL in the display area DA, or the scan driver SIC in the non-display area NDA. In an embodiment, the fan-out line FOL may be electrically connected to the data line DL to provide a data voltage to the transistor TR, for example. The fan-out line FOL may be electrically connected to the voltage line VL to provide a supply voltage to the transistor TR. The fan-out line FOL may be electrically connected to the scan driver SIC to provide a scan control signal to the scan driver SIC. The data line DL and the voltage line VL in the display area DA may be electrically connected to the transistor TR, and the scan driver SIC may generate scan signals. Accordingly, the fan-out line FOL may apply the data voltage or the supply voltage received from the display driver DIC on the flexible film FPCB to the transistor TR of the pixel, and may provide it to the scan driver SIC through a scan control signal received from the flexible film FPCB. As the display device 10 includes the fan-out lines FOL disposed in the display area DA, the non-display area NDA may be reduced.

The connection electrode CNE may electrically connect the source electrode SE of the transistor TR with the pixel electrode AE of the light-emitting element ED. The connection electrode CNE may be inserted into a contact hole penetrating the inter-dielectric layer ILD and the gate insulator GI to be connected to the source electrode SE of the transistor TR. The connection electrode CNE may supply the driving current received from the pixel circuit to the light-emitting element ED.

The data line DL may be extended in the y-axis direction in the display area DA. The data line DL may be electrically connected to the drain electrode DE or gate electrode GE of the transistor TR. Accordingly, the data line DL may apply the data voltage to the transistor TR.

The voltage line VL may be extended in the y-axis direction in the display area DA. The voltage line VL may be electrically connected to the transistor TR or the light-emitting element ED. In an embodiment, the voltage line VL may be, but is not limited to, a high-level line, a low-level line, or a sensing line, for example. The voltage line VL may apply the supply voltage to the transistor TR or the light-emitting element ED.

The passivation layer PAS may be disposed on the third metal layer MTL3 and the inter-dielectric layer ILD. The passivation layer PAS may protect the transistor TR. The passivation layer PAS may define a contact hole through which the pixel electrode AE passes.

The via layer VIA may be disposed on the passivation layer PAS. The via layer VIA may provide a flat surface over the transistor layer TRL. The via layer VIA may include an organic insulating material such as PI. The via layer VIA may define a contact hole through which the pixel electrode AE passes.

The light-emitting element layer EML may be disposed on the transistor layer TRL. The light-emitting element layer EML may include a light-emitting element ED and a pixel-defining layer PDL.

The light-emitting element ED may be disposed in the emission area EA on the via layer VIA. The light-emitting element ED of each of the pixels may include the pixel electrode (or an anode electrode) AE, an emissive layer EL, and a common electrode (or a cathode electrode) CE. The pixel electrode AE may be disposed on the via layer VIA. The pixel electrode AE may overlap with one of the plurality of emission areas EA defined by the pixel-defining layer PDL. The pixel electrode AE may be inserted into the contact hole penetrating the via layer VIA and the passivation layer PAS and connected to the connection electrode CNE. In an embodiment, the pixel electrode AE may receive a driving current from the pixel circuit through the connection electrode CNE, for example.

The emissive layer EL may be disposed on the pixel electrode AE. In an embodiment, the emissive layer EL may be, but is not limited to, an organic emissive layer including an organic material, for example. When the emissive layer EL is an organic light-emitting layer, when the pixel circuit of the pixel applies a predetermined voltage to the pixel electrode AE and the common electrode CE receives a common voltage or cathode voltage, holes may move to the emissive layer EL through a hole transporting layer and electrons may move to the emissive layer EL through a hole transporting layer, and they combine in the emissive layer EL to emit light.

The common electrode CE may be disposed on the emissive layer EL. In an embodiment, the common electrode CE may be implemented as an electrode common to all pixels, instead of being disposed as a separated electrode for each of the pixels, for example. The common electrode CE may be disposed on the emissive layer EL in the emission areas and may be disposed on the pixel-defining layer PDL in the other areas different from the emission area.

The pixel-defining layer PDL may be disposed in a light-blocking area BA on the via layer VIA. The pixel-defining layer PDL may define a plurality of emission areas EA or a plurality of openings. The pixel-defining layer PDL may separate and insulate the pixel electrodes AE of the pixels from one another.

The encapsulation layer TFEL may be disposed on the common electrode CE to cover the light-emitting elements ED. The encapsulation layer TFEL may include at least one inorganic film to prevent permeation of oxygen or moisture into the light-emitting elements ED. The encapsulation layer TFEL may include at least one organic film to protect the light-emitting elements ED from particles such as dust.

The touch sensing unit TSU may be disposed on the encapsulation layer TFEL. The touch sensing unit TSU may include touch electrodes TE, a first insulating layer IL1, a bridge electrode BRG, and a second insulating layer IL2.

The touch electrodes TE may be disposed in the light-blocking area BA on the encapsulation layer TFEL. The touch electrodes TE may detect a user's touch by capacitive sensing. In an embodiment, the touch sensing unit TSU may sense a user's touch by mutual capacitance sensing conducted at points between a plurality of touch electrodes TE, or by self-capacitance sensing conducted on each of a plurality of touch electrodes TE, for example. The touch electrodes TE may include or consist of a single layer of molybdenum (Mo), titanium (Ti), copper (Cu), aluminum (Al), or indium tin oxide (“ITO”), or may include or consist of a stack structure of aluminum and titanium (Ti/Al/Ti), a stack structure of aluminum and ITO (“ITO/Al/ITO”), an aluminum polymer composite (“APC”) alloy or a stack structure of an APC alloy and ITO (“ITO/APC/ITO”).

The first insulating layer IL1 may be disposed on the touch electrodes TE and the encapsulation layer TFEL. The first insulating layer IL1 may have insulating and optical functionalities. In an embodiment, the first insulating layer IL1 may be an inorganic layer including at least one selected from the group including: a silicon nitride layer, a silicon oxynitride layer, a silicon oxide layer, a titanium oxide layer and an aluminum oxide layer, for example. In another embodiment, the first insulating layer IL1 may include an organic film.

The bridge electrode BRG may be disposed on the first insulating layer IL1. The bridge electrode BRG may be disposed in a different layer from the touch electrodes TE to electrically connect between adjacent touch electrodes TE.

The second insulating layer IL2 may be disposed on the bridge electrode BRG and the first insulating layer IL1. The second insulating layer IL2 may have insulating and optical functions. The second insulating layer IL2 may include or consist of one of the above-listed materials as the material of the first insulating layer IL1.

The polarizing film POL may be disposed on the second insulating layer IL2. The polarizing film POL may be attached on the touch sensing unit TSU by an OCA film or an OCR. In an embodiment, the polarizing film POL may include a linear polarizer and a retarder film, for example. The retarder film may be a λ/4 plate (quarter-wave plate). The retarder film and the linear polarizer may be sequentially stacked on the touch sensing unit TSU. The polarizing film POL may reduce reflection of external light to prevent color distortion due to the reflection of external light.

The flexible film FPCB may be disposed under the substrate SUB. A part of the flexible film FPCB may be inserted into the opening SOP of the substrate SUB and electrically connected to the pad PAD. Another part of the flexible film FPCB may be attached to the lower surface of the substrate SUB using an adhesive member ADM. The flexible film FPCB may include a lead electrode LDE disposed on one side of the upper surface and inserted into the opening SOP. The lead electrode LDE may protrude from one side of the flexible film FPCB, and a part of the lead electrode LDE may not overlap the flexible film FPCB. The upper surface of the lead electrode LDE may contact a part of the pad PAD. A part of the lower surface of the lead electrode LDE may be electrically connected to another part of the pad PAD through the contact part CTP. The flexible film FPCB may support the display driver DIC disposed on the lower surface on the opposite side. The lead electrode LDE may be electrically connected to the display driver DIC through a lead line (not shown) disposed on the lower surface of the flexible film FPCB. An opposite side of the flexible film FPCB may be connected to a source circuit board (not shown) under the substrate SUB. The flexible film FPCB may transmit signals and voltages from the display driver DIC to the display area DA. The flexible film FPCB may supply a scan control signal to the scan driver SIC.

The contact part CTP may cover the lower surface of the lead electrode LDE protruding from the flexible film FPCB and the lower surface of the pad PAD exposed through the opening SOP. The contact part CTP may supplement electrical connection between the lead electrode LDE and the pad PAD, and may stably fix the lead electrode LDE to the lower surface of the pad PAD. The contact part CTP may include metal powder and a polymer. In an embodiment, the metal powder may include or consist of metal particles such as silver (Ag) and copper (Cu), and the polymer may include an acrylic resin or an epoxy resin, for example. It should be understood, however, that the disclosure is not limited thereto. As the contact part CTP may include or consist of metal powder, it may have conductivity, and may include a polymer as a binder connecting metal particles.

The contact part CTP may be formed by printing a metal paste including or consisting of metal particles, a monomer and a solvent in an opening SOP of the substrate SUB using a silicon pad, and then sintering it using a laser. During the sintering process, the monomer reacts into a polymer by heat from a laser and accordingly the metal particles are brought into close contact with each other and aggregated, so that the predetermined resistance of the contact part CTP may be lowered.

The display driver DIC may be disposed (e.g., mounted) on the flexible film FPCB. The display driver DIC may be an IC. The display driver DIC may convert digital video data into analog data voltage based on a data control signal from a timing controller (not shown), and the analog data voltage may be applied to the data lines DL in the display area DA through the flexible film FPCB. The display driver DIC may supply the power voltage received from the power supply unit (not shown) to the power lines VL in the display area DA through the flexible film FPCB. As the display device 10 includes the fan-out lines FOL disposed on the substrate SUB, the flexible film FPCB and the display driver DIC disposed under the first substrate SUB1, the non-display area NDA may be reduced.

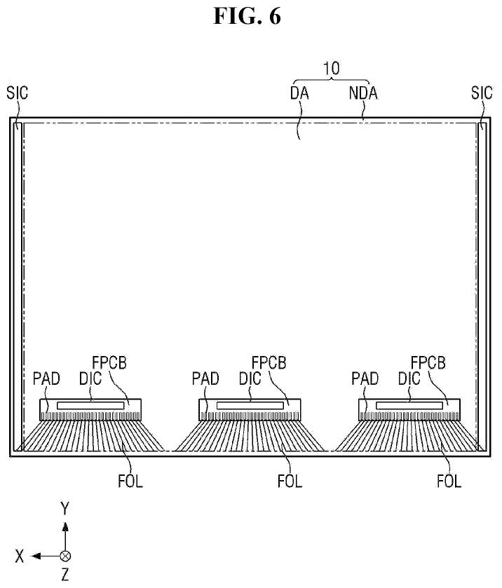

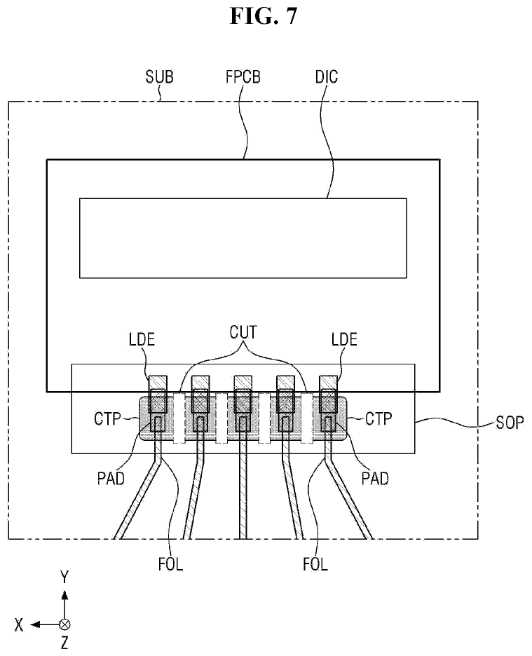

FIG. 6 is a view showing an embodiment of the bottom of a display device according to the disclosure. FIG. 7 is an enlarged view showing an embodiment of a part of the bottom of the display device in the embodiment of the disclosure.

Referring to FIGS. 6 and 7, flexible films FPCB, display drivers DIC, pads PAD, and fan-out lines FOL may be disposed in the display area DA.

The fan-out lines FOL may be connected to the pads PAD. The fan-out lines FOL may be extended from the pads PAD to the edge of the display area DA. In an embodiment, the fan-out lines FOL may be extended from the pads PAD toward the lower edge of the display area DA, for example. The fan-out lines FOL may be electrically connected to the data lines DL and voltage lines VL in the display area DA, or the scan driver SIC in the non-display area NDA.

The flexible films FPCB may be disposed under the substrate SUB. The flexible films FPCB may be disposed at the edge of the lower surface of the display device 10. The flexible films FPCB may supply, but is not limited to, data voltages, supply voltages, and scan control signals. The display drivers DIC may be disposed (e.g., mounted) on the flexible films FPCB. The display drivers DIC may supply data voltages and supply voltages to the display panel 100 through the flexible films FPCB.

A part of the flexible film FPCB may be inserted into the opening SOP of the substrate SUB and electrically connected to the pad PAD. Another part of the flexible film FPCB may be attached to the lower surface of the substrate SUB. The flexible film FPCB may include a lead electrode LDE inserted into the opening SOP. The lead electrode LDE may protrude from one side of the flexible film FPCB. One surface of the lead electrode LDE may contact a part of the pad PAD. A part of an opposite surface of the lead electrode LDE may be electrically connected to another part of the pad PAD through the contact part CTP. A plurality of pads PAD may be associated with a plurality of lead electrodes LDE, respectively.

The contact part CTP may cover the lower surface of the lead electrode LDE and the lower surface of the pad PAD. The contact part CTP may supplement electrical connection between the lead electrode LDE and the pad PAD, and may stably fix the lead electrode LDE to the lower surface of the pad PAD. The contact part CTP may include metal powder and a polymer. In an embodiment, the metal powder may include or consist of metal particles such as silver (Ag) and copper (Cu), and the polymer may include an acrylic resin or an epoxy resin, for example. It should be understood, however, that the disclosure is not limited thereto. As the contact part CTP may include or consist of metal powder, it may have conductivity, and may include a polymer as a binder connecting metal particles.

The contact part CTP may be formed by printing a metal paste including or consisting of metal particles, monomers and a solvent in an opening SOP of the substrate SUB using a silicon pad, and then sintering it using a laser. During the sintering process, the monomer reacts into a polymer by heat from a laser and accordingly the metal particles are brought into close contact with each other and aggregated, so that the predetermined resistance of the contact part CTP may be lowered.

The sintered metal paste may cover the plurality of pads PAD as well as the plurality of lead electrodes LDE inserted into one opening SOP. A plurality of cuts CUT formed during a laser patterning process may separate the plurality of contact parts CTP. The contact parts CTP may be separated from adjacent ones by the cuts CUT, and one contact part CTP may electrically connect one pad PAD with one lead electrode LDE.

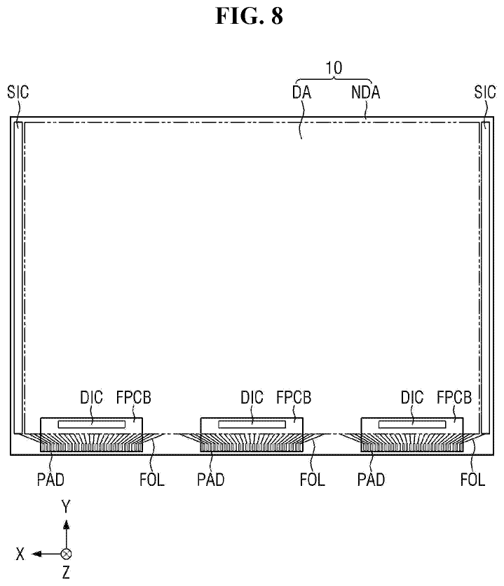

FIG. 8 is a view showing an embodiment of the bottom of a display device according to the disclosure.

Referring to FIG. 8, fan-out lines FOL and pads PAD may be disposed in the non-display area NDA. The fan-out lines FOL may be connected to the pads PAD. The fan-out lines FOL may be extended from the pads PAD to the edge of the display area DA. In an embodiment, the fan-out lines FOL may be extended from the pads PAD toward the lower edge of the display area DA, for example. The fan-out lines FOL may be electrically connected to the data lines DL and voltage lines VL in the display area DA, or the scan driver SIC in the non-display area NDA.

The flexible films FPCB may be disposed in the display area DA and the non-display area NDA, and display driver DIC may be disposed in the display area DA. The flexible films FPCB may be disposed under the substrate SUB. The flexible films FPCB may be disposed at the edge of the lower surface of the display device 10. The flexible films FPCB may supply, but is not limited to, data voltages, supply voltages, and scan control signals. The display drivers DIC may be disposed (e.g., mounted) on the flexible films FPCB. The display drivers DIC may supply data voltages and supply voltages to the display panel 100 through the flexible films FPCB.

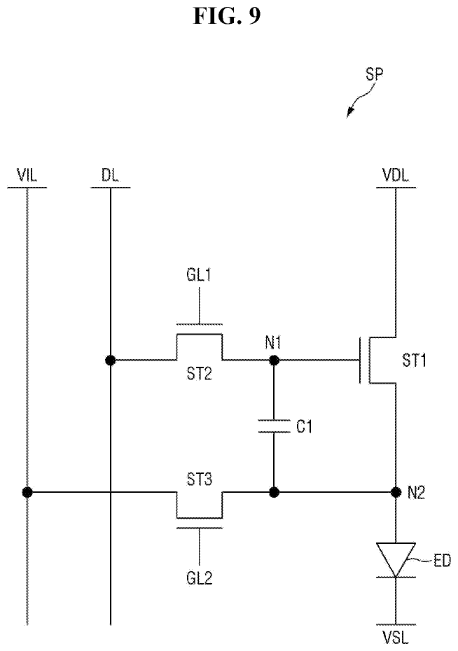

FIG. 9 is a circuit diagram showing an embodiment of a pixel of a display device according to the disclosure.

Referring to FIG. 9, a pixel SP may include a pixel circuit and a light-emitting element ED. The pixel circuit may include first to third transistors ST1, ST2 and ST3 and a first capacitor CL.

The first transistor ST1 may include a gate electrode, a drain electrode, and a source electrode. The gate electrode of the first transistor ST1 may be connected to a first node N1, the drain electrode thereof may be connected to a high-level line VDL, and the source electrode thereof may be connected to a second node N2. The high-level line VDL may supply a high-level voltage to the first transistor ST1. The first transistor ST1 may control a drain-source current (or a driving current) based on a data voltage applied to the gate electrode.

The pixel SP may include at least one light-emitting element ED. When the pixel SP includes a plurality of light-emitting elements ED, the plurality of light-emitting elements ED may be connected in series or in parallel. The light-emitting element ED may emit light by receiving a driving current from the first transistor ST1. The amount or the brightness of the light emitted from the light-emitting element ED may be proportional to the magnitude of the driving current. The light-emitting element ED may include an organic LED including an organic light-emitting layer, a quantum-dot LED including a quantum-dot light-emitting layer, an inorganic LED including an inorganic semiconductor, or a micro LED.

A first electrode of the light-emitting element ED may be connected to the second node N2, and a second electrode of the light-emitting element ED may be connected to a low-level voltage line VSL. The first electrode of the light-emitting element ED may be connected to the source electrode of the first transistor ST1, the drain electrode of the third transistor ST3, and the second capacitor electrode of the first capacitor C1 through the second node N2. The low-level voltage line VSL may supply a low-level voltage to the second electrode of the light-emitting element ED.

The second transistor ST2 may be turned on by a first scan signal of the first scan line GL1 to electrically connect the data line DL with the first node N1, which is the gate electrode of the first transistor ST1. The second transistor ST2 may be turned on in response to the first scan signal to apply data voltage to the first node N1. The gate electrode of the second transistor ST2 may be connected to the first scan line GL1, the drain electrode thereof may be connected to the data line DL, and the source electrode thereof may be connected to the first node N1.

The third transistor ST3 may be turned on by a second scan signal of the second scan line GL2 to electrically connect the initialization voltage line VIL with the second node N2, which is the source electrode of the first transistor ST1. The third transistor ST3 may be turned on in response to the second scan signal to apply an initialization voltage to the second node N2 and to supply a sensing signal to the initialization voltage line VIL. The gate electrode of the third transistor ST3 may be connected to the second scan line GL2, the drain electrode may be connected to the second node N2, and the source electrode may be connected to the initialization voltage line VIL.

The first capacitor C1 may include a first capacitor electrode and a second capacitor electrode. The first capacitor electrode of the first capacitor C1 may be connected to the first node N1, and the second capacitor electrode of the first capacitor C1 may be connected to the second node N2. Accordingly, the first capacitor C1 may maintain a potential difference between the gate electrode and the source electrode of the first transistor ST1.

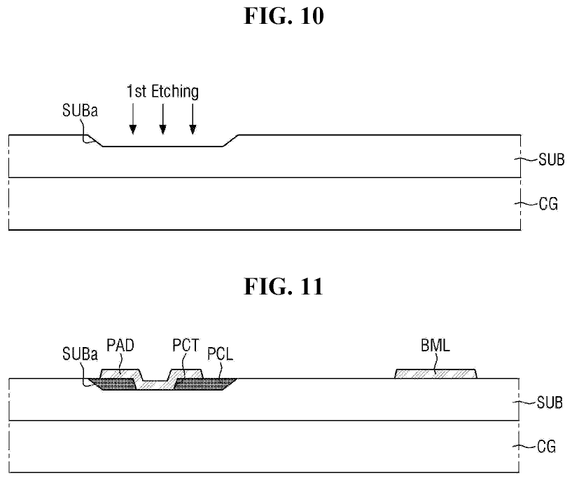

FIGS. 10 to 15 are cross-sectional views showing an embodiment of processing operations of fabricating a display device according to the disclosure. In the following description, the same elements as those described above will be briefly described or omitted.

In FIG. 10, a carrier substrate CG may support a display device 10 during the processes of fabricating the display device 10. In an embodiment, the carrier substrate CG may be, but is not limited to, a carrier glass, for example.

The substrate SUB may be disposed on the carrier substrate CG. The substrate SUB may be a base substrate or a base member. In an embodiment, the substrate SUB may be, but is not limited to, a rigid substrate including glass material or metal material, for example. In another embodiment, the substrate SUB may be a flexible substrate including a polymer resin such as PI.

A groove may be defined in the substrate SUB via a first etching process. A first side surface SUBa of the substrate SUB may surround the groove of the substrate SUB. The first etching process of the substrate SUB may include at least one of: a wet etching process, a dry etching process, a plasma etching process, and a laser etching process. The first side surface SUBa of the substrate SUB may be formed by etching from the upper surface of the substrate SUB, and may be adjacent to the upper surface of the substrate SUB. The first side surface SUBa of the substrate SUB may be inclined at a first angle θ1 relative to a same plane as that of the upper surface of the substrate SUB.

In FIG. 11, a pad clad PCL is accommodated in the groove of the substrate SUB, so that it may be surrounded by the first side surface SUBa of the substrate SUB. The upper surface of the pad clad PCL may be flush with the upper surface of the substrate SUB, but the disclosure is not limited thereto. The pad clad PCL may include a pad contact hole PCT into which a pad PAD is inserted. In an embodiment, the pad clad PCL may include, but is not limited to, a polymer resin such as PI, or an insulating material such as silicon nitride (SiNx) and silicon (Si).

The first metal layer MTL1 may be disposed on the substrate SUB and the pad clad PCL. The first metal layer MTL1 may include a pad PAD and a light-blocking layer BML.

The pad PAD may be disposed on the pad clad PCL and inserted into the pad contact hole PCT formed in the pad clad PCL. The pad PAD may be inserted into the pad contact hole PCT and temporarily contact one surface of the substrate SUB.

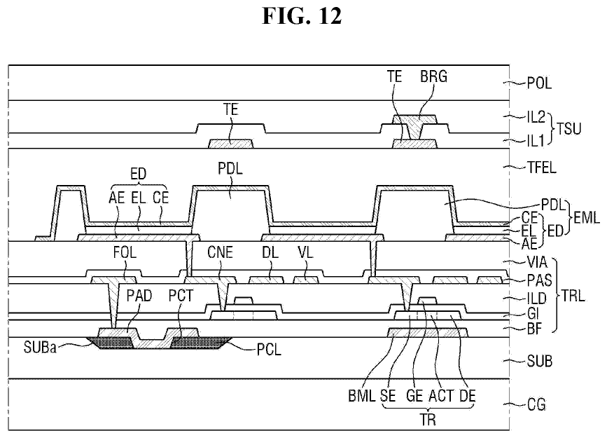

In FIG. 12, a buffer layer BF, an active layer ACTL, a gate insulator GI, a second metal layer MTL2, an inter-dielectric layer ILD, a third metal layer MTL3, a passivation layer PAS and a via layer VIA may be sequentially stacked on the first metal layer MTL1.

The light-emitting element layer EML may be disposed on the transistor layer TRL. The light-emitting element layer EML may include a light-emitting element ED and a pixel-defining layer PDL.

The encapsulation layer TFEL may be disposed on the common electrode CE to cover the light-emitting elements ED.

The touch sensing unit TSU may be disposed on the encapsulation layer TFEL and include a plurality of touch electrodes and a plurality of touch lines.

The polarizing film POL may be disposed on the touch sensing unit TSU. The polarizing film POL may be attached on the touch sensing unit TSU by an OCA film or an OCR.

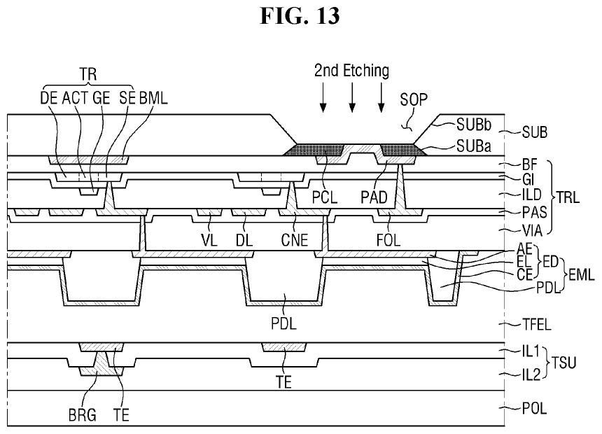

In FIG. 13, the display device 10 under fabrication may be inverted vertically to attach the flexible film FPCB. The carrier substrate CG may be removed from the substrate SUB. In an embodiment, the carrier substrate CG may be removed from the lower surface of the substrate SUB using a sacrificial layer (not shown) disposed between the carrier substrate CG and the substrate SUB, for example, but the disclosure is not limited thereto.

The opening SOP of the substrate SUB may be defined via a second etching process of the substrate SUB, and the second side surface SUBb of the substrate SUB may surround the opening SOP. The second etching process of the substrate SUB may include at least one of: a wet etching process, a dry etching process, a plasma etching process, and a laser etching process. The opening SOP may be defined in the substrate SUB to expose the pad clad PCL and the pad PAD. The pad clad PCL may protect the transistor layer TRL except for the pad PAD during the secondary etching process of the substrate SUB.

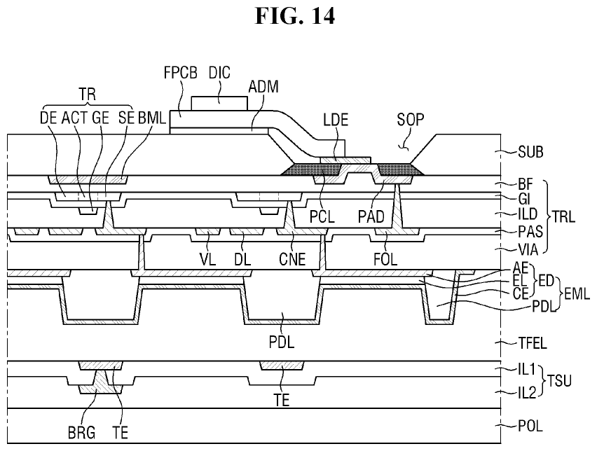

In FIG. 14, the flexible film FPCB may be disposed on one surface of the substrate SUB. The flexible film FPCB and the lead electrode LDE may be aligned on the pad PAD via an alignment process. A part of the flexible film FPCB may be inserted into the opening SOP of the substrate SUB and electrically connected to the pad PAD. Another part of the flexible film FPCB may be attached to the lower surface of the substrate SUB using an adhesive member ADM. The lead electrode LDE may protrude from one side of the flexible film FPCB. One surface of the lead electrode LDE may contact a part of the pad PAD.

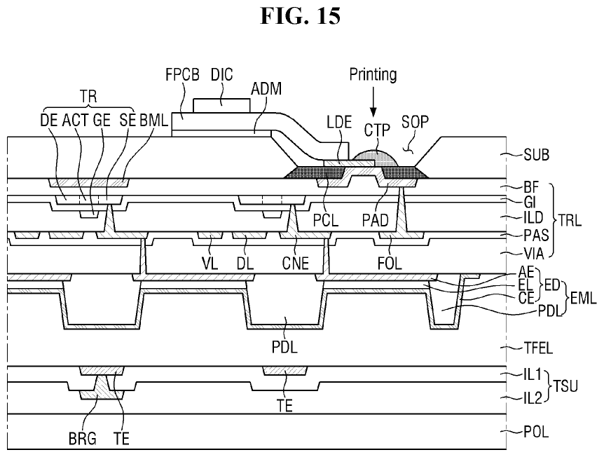

In FIG. 15, the contact part CTP may cover a part of the lead electrode LDE and a part of the pad PAD. A part of an opposite surface of the lead electrode LDE may be electrically connected to another part of the pad PAD through the contact part CTP. The contact part CTP may supplement electrical connection between the lead electrode LDE and the pad PAD, and may stably fix the lead electrode LDE to one surface of the pad PAD. The contact part CTP may include metal powder and a polymer. In an embodiment, the metal powder may include or consist of metal particles such as silver (Ag) and copper (Cu), and the polymer may include an acrylic resin or an epoxy resin, for example. It should be understood, however, that the disclosure is not limited thereto. As the contact part CTP may include or consist of metal powder, it may have conductivity, and may include a polymer as a binder connecting metal particles.

The contact parts CTP may be formed by printing a metal paste including or consisting of metal particles, monomers and a solvent in an opening SOP of the substrate SUB using a silicon pad, and then sintering it using a laser. During the sintering process, the monomer reacts into a polymer by heat from a laser and accordingly the metal particles are brought into close contact with each other and aggregated, so that the predetermined resistance of the contact part CTP may be lowered.

The sintered metal paste may cover the plurality of pads PAD as well as the plurality of lead electrodes LDE inserted into one opening SOP. A plurality of cuts CUT formed during a laser patterning process may separate the plurality of contact parts CTP. The contact parts CTP may be separated from adjacent ones by the cuts CUT, and one contact part CTP may electrically connect one pad PAD with one lead electrode LDE.

Therefore, in the display device 10, the lead electrode LDE and the pad PAD are fixed by the contact part CTP, so that the lead electrode LDE of the flexible film FPCB may be electrically connected to the pad PAD without using ultrasonic bonding or thermocompression bonding. The contact part CTP may supplement electrical connection between the lead electrode LDE and the pad PAD, and may easily connect the lead electrode LDE with the pad PAD. In addition, by simplifying the fabrication process of the display device 10, it is possible to save the fabrication time and cost.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

What is claimed is:

1. A display device comprising:
a substrate which includes a first side surface adjacent to an upper surface and a second side surface adjacent to a lower surface, and in which an opening surrounded by the second side surface is defined;
a pad clad surrounded by the first side surface of the substrate and including a pad contact hole;
a pad disposed on the pad clad and inserted into the pad contact hole;
a fan-out line disposed on the pad and electrically connected to the pad;
a transistor electrically connected to the fan-out line; and
a flexible film disposed under the substrate and including a lead electrode inserted into the opening of the substrate and in contact with the pad.

2. The display device of claim 1, further comprising:
a contact part covering a lower surface of the lead electrode and a lower surface of the pad to electrically connect the lead electrode with the pad.

3. The display device of claim 2, wherein the lead electrode protrudes from one side of the flexible film, and wherein the contact part covers the lower surface of the lead electrode protruding from the flexible film.

4. The display device of claim 1, wherein an upper surface of the pad clad is flush with the upper surface of the substrate.

5. The display device of claim 1, wherein the pad clad includes at least one of polyimide, silicon nitride (SiNx), and silicon (Si).

6. The display device of claim 1, wherein the pad clad is exposed through the opening of the substrate.

7. The display device of claim 1, wherein the first side surface of the substrate is inclined at a first angle with respect to a same plane as a plane of the upper surface of the substrate, and the second side surface of the substrate is inclined at a second angle with respect to a same plan as the lower surface of the substrate, and wherein the first angle is smaller than the second angle.

8. The display device of claim 7, wherein a vertical thickness of the first side surface is smaller than a vertical thickness of the second side surface.

9. The display device of claim 2, wherein the contact part is formed using a metal paste including silver (Ag) or copper (Cu).

10. The display device of claim 1, further comprising:
a display area which displays images; and
a non-display area surrounding the display area,
wherein the pad and the flexible film are disposed in the display area.

11. The display device of claim 1, further comprising:
a display area which displays images;
a non-display area surrounding the display area; and
a display driver which is disposed on the flexible film and applies a data voltage to the transistor,
wherein the pad and the fan-out line are disposed in the non-display area, and the display driver is disposed in the display area.

12. The display device of claim 1, further comprising:
a transistor layer comprising the transistor;
a light-emitting element layer disposed on the transistor layer and comprising a light-emitting element; and
an encapsulation layer covering upper and side surfaces of the light-emitting element layer.

13. The display device of claim 1, further comprising:
a transistor layer comprising the transistor;
a light-emitting element layer disposed on the transistor layer and comprising a light-emitting element;
an encapsulation substrate disposed on the light-emitting element layer; and
a sealing member disposed along edges of the substrate and the encapsulation substrate between the substrate and the encapsulation substrate to attach the substrate and the encapsulation substrate to each other.

14. A method of fabricating a display device, the method comprising:
providing a substrate;
defining a groove in the substrate by performing a first etching process on an upper surface of the substrate;
forming a pad clad which is accommodated in the groove and includes a pad contact hole;
forming a pad disposed on the pad clad and inserted into the pad contact hole;
forming a transistor on the pad and forming a fan-out line electrically connecting the pad with the transistor;
defining an opening exposing the pad by performing a secondary etching process on a lower surface of the substrate; and
inserting one side of a flexible film into the opening to bring a lead electrode of the flexible film in contact with the pad.

15. The method of claim 14, further comprising:
forming a contact part electrically connecting the pad with the lead electrode by covering a part of the pad and a part of the lead electrode.

16. The method of claim 15, wherein the forming the contact part comprises printing a metal paste on the opening of the substrate and then sintering the metal paste.

17. The method of claim 16, wherein the forming the contact part further comprises separating a sintered metal paste into a plurality of contact parts via a laser patterning process.

18. The method of claim 14, wherein the forming the pad clad comprises disposing an upper surface of the pad clad so that the upper surface of the pad clad is flush with the upper surface of the substrate.

19. The method of claim 14, wherein the defining the groove in the substrate comprises forming a first side surface inclined at a first angle from a same plane as a plane of the upper surface of the substrate,
Wherein the defining the opening comprises forming a second side surface inclined at a second angle from a same plane as a plane of the lower surface of the substrate, and
wherein the first angle is smaller than the second angle.

20. The method of claim 14, wherein a thickness of the pad clad is smaller than a depth of the opening.
